(19) United States
(12) Patent Application Publication
(10) Pub. No.: US 2012/0103379 A1
(43) Pub. Date: May 3, 2012

(54) THERMOELECTRIC GENERATOR INCLUDING A THERMOELECTRIC MODULE HAVING A MEANDERING P-N SYSTEM

(76) Inventors: Ilona Krinn, Moehringen (DE); Wolfgang Stoecklein, Waiblingen (DE); Manfred Schmitt, Heppenheim (DE); Ludwig Kemmler, Kusterdingen-Maehringen (DE)

(21) Appl. No.: 13/287,662

(22) Filed: Nov. 2, 2011

(30) Foreign Application Priority Data
Nov. 3, 2010 (DE) 102010043281.4

(51) Int. Cl. H01L 35/32; H01L 35/34

(52) U.S. Cl. 136/212; 136/224; 136/201

(57) ABSTRACT

A thermoelectric module having a plurality of p-n-couples, every two adjacent p-n-legs forming one p-n-couple. The p-n-legs are each manufactured from conductive materials. The p-n-legs of the plurality of p-n-couples are separated in an alternating sequence by an electrically insulating gap which creates a meandering current flow.

### CROSS REFERENCE

The present application claims the benefit under 35 U.S.C. §119 of German Patent Application No. DE 102010043281.4 filed on Nov. 3, 2010, which is expressly incorporated herein by reference in its entirety.

### BACKGROUND INFORMATION

Waste heat, for example from power plants or motor vehicles, is often released unused into the environment. Effectively utilizing this heat energy would, however, result in a higher efficiency. One possibility of utilizing this waste heat are thermoelectric generators (TEG) which, in case of a temperature difference, generate an electric voltage due to the Seebeck effect, also referred to as thermoelectric effect. Devices for generating energy from waste heat are described in German Patent Application No. DE 10 2008 005 334 A1, for example.

Thermoelectric generators have been hitherto often employed in the form of a stack system. This is described in German Patent Application No. DE 10 2005 009 480 A1, for example. In this system, thermoelectric modules (TEM) alternate with other heat exchanger components (cold and hot sides) in stacks above each other. These stacks are braced mechanically. By putting the thermoelectric modules in stacks, additional heat transfers develop, resulting in heat losses which reduce the efficiency of the thermoelectric generator. Moreover, if a mechanical bracing is provided, the total weight of the thermoelectric generator increases due to the bracing components.

German Patent No. DE 103 33 084 A1 also describes a thermoelectric generator having a stack system in which the thermoelements are, however, not positioned flush above one another and in which, in a possible embodiment variant, the legs of the thermoelements are positioned in a meandering pattern on a carrier foil. As a result, the consecutive thermoelectric points of contact in the thermoelement chain, preferably metallic contact bridges, may be positioned in such a way that they are very dense and a big distance apart from the opposite edges of the thermoelements. This system allows a simplified, mechanically stable construction and has an advantageous effect on the long-term stability of the thermoelement chain; the efficiency does, however, not improve. In addition, preparing the thermoelements on the carrier foils preferably includes thin-film deposition of thermoelectric materials and metals, as well as subsequent structuring with the aid of wet chemical etching, which is associated with high expenditures in terms of time and materials during the manufacturing.

### SUMMARY

With the aid of an example p-n-legs construction according to the present invention, the number of heat transfers is reduced, thereby improving the efficiency of the thermoelectric generator. Since a mechanical bracing used in the conventional stack system is omitted, the weight of the components is additionally reduced so that a weight-reduced and compact component having reduced manufacturing costs is obtained.

Another advantage of the example system according to the present invention is the possibility of achieving an integral thermal and electric connection due to the good accessibility. In addition, due to the direct contact of the p-n-thermocouples, the thermoelement legs do not need to be angled, resulting in savings with respect to the used material, the weight, and the process time due to omitting one assembly step.

The prerequisite for recovering thermoelectric energy is a sufficiently big temperature difference which is generated with the aid of a heat source (e.g., exhaust gas) and a heat sink (e.g., cooling water). The thermoelectric generator is positioned in between. The temperature difference between the hot and the cold sides of the thermoelectric generator corresponds to a certain heat flow. The thermoelectric generator converts some of this heat flow into electrical power.

The thermoelectric generator may be constructed of multiple thermoelectric modules which are composed of a plurality of thermoelectric elements.

A thermoelectric module includes multiple p-n-legs, the adjacent legs each being manufacturable from different materials. Forming the thermoelements from p- and n-conductive semiconductors is particularly preferred, since these distinguish themselves in terms of a strong thermoelectric effect, in particular a high Seebeck coefficient, and, in addition, a structuring technology is available for p- (positive, electron deficiency) and n- (negative, electron excess) conductive semiconductor combinations.

In this case, the individual p-n-legs are aligned in such a way that they are connected electrically in series and thermally in parallel, and p-conductive and n-conductive legs alternate.

### BRIEF DESCRIPTION OF THE DRAWINGS

The present invention is described below in greater detail on the basis of example embodiments and the figures.

FIG. 1 shows a front view of a conventional thermoelement.

FIG. 2 shows a front view of a thermoelectric generator having a meandering system of p- and n-legs in a block.

FIG. 3 shows a perspective view of the block of p- and n-legs, in the form of stripes.

### DETAILED DESCRIPTION OF EXAMPLE EMBODIMENTS

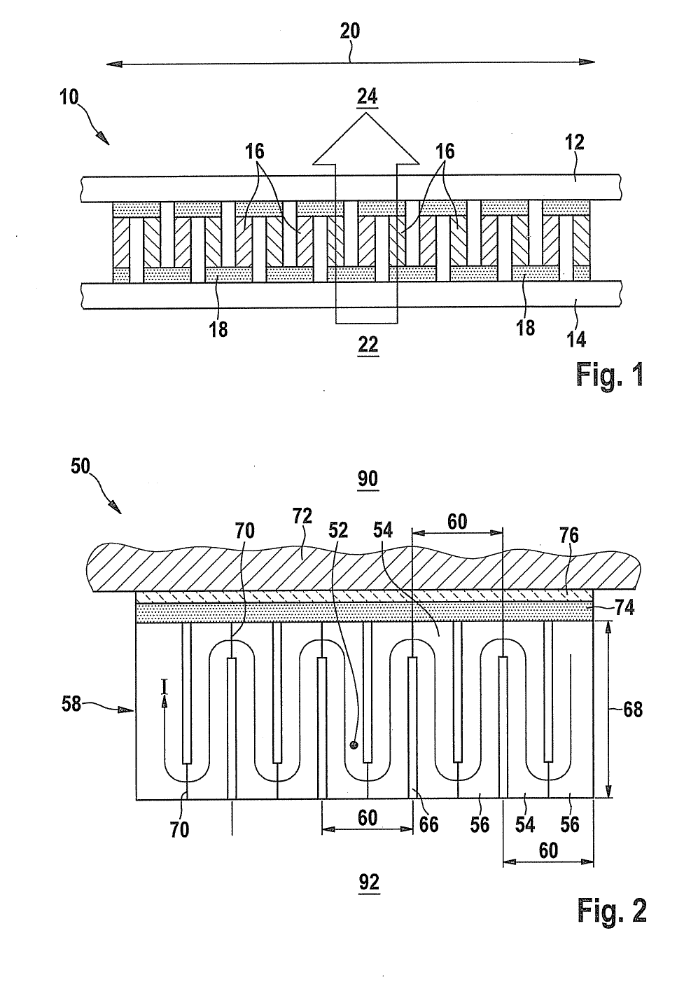

For the purpose of better explaining the present invention, FIG. 1 shows a conventional thermoelement or a conventional thermoelectric module 10.

A thermoelectric module 10 is usually composed of two thin electrically insulating plates 12, 14 between which small blocks 16 made of different material are positioned. Every two blocks 16 of different material are connected with each other via contact isles 18 in such a way that they form an electric series circuit 20. One of the two plates 12 absorbs inflowing heat flow 22 (hot side), while the other plate 14 gives off outflowing heat flow 24 (cold side). The heat flow, which flows from the hot to the cold side, flows parallel through all blocks 16.

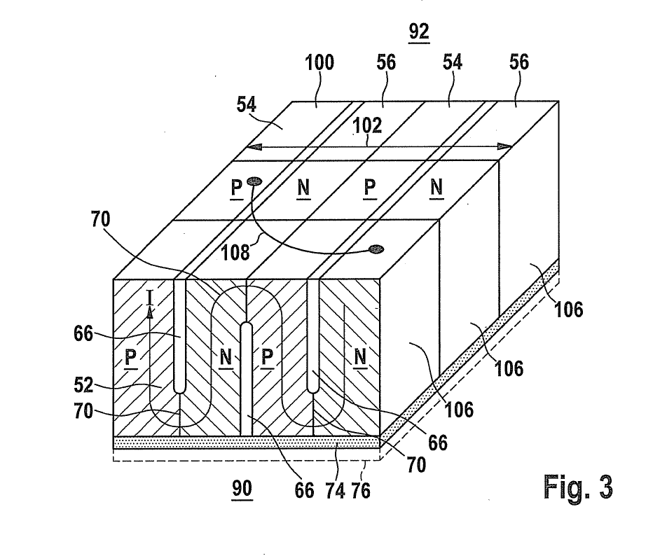

FIG. 2 shows a front view of an example thermoelectric module 50 according to the present invention having a plurality of p- and n-legs 54, 56 which are positioned in series in a block 58. One p-n-couple 60 is formed by a conductor pair made of semiconductor materials that is connected at one end 62 and uses the thermoelectric effect. In the exemplary embodiment illustrated here according to FIGS. 2 and 3, each p-n-couple 60 includes one p-doped semiconductor 54 and one n-doped semiconductor 56.

A plurality of p-n-couples 60, in the form of legs 54, 56, is positioned in series next to each other in a block 58. Adjacent legs 54, 56 are each manufactured of p-n-conductive materials.

On a boundary line between two adjacent legs 54, 56, which form one p-n-couple 60, both legs 54, 56 are partially separated and thus electrically insulated so that a gap 66 forms. The length of gap 66 is indicated in FIG. 2 with the aid of reference numeral 68.

The separation does not take place completely but in such a way that two adjacent legs 54, 56 remain connected via a bridge 70. Bridge 70 represents an electrical contact since p- and n-legs 54, 56 of p-n-couples 60 are electrically and thermally connected to each other in the area of bridge 70.

Gap 66 may limit the heat conductivity. Gap 66 for electric insulation of p-n-legs 54, 56 of p-n-couples 60 from each other is created with the aid of a metal-cutting manufacturing technique, e.g., sawing, cutting or milling. The electric insulation may take place through air or doping using a non-conductive material, or gap 66 is filled up with an electrically insulating material.

Block 58 is connected to housing 72 of a heat exchanger via an electrically insulating layer 74 made of ceramic material or a non-conductive adhesive, for example. Additionally, a layer 76, which mechanically decouples block 58 from housing 72 of the heat exchanger, may be introduced between electrically insulating layer 74 and housing 72 of the heat exchanger. Utilizing a non-conductive adhesive in the form of an electrically insulating layer 74 has the advantage that the electrically insulating layer 74 simultaneously forms layer 76 which mechanically decouples the block from housing 72 of the heat exchanger.

Electrically insulating layer 74 for connecting block 58 to housing 72 of the heat exchanger may, for example, be manufactured using the low-temperature sintering process or coating, for example using an aluminum oxide layer, e.g., AL₂O₃.

A further embodiment variant is obtained by manufacturing the entire heat exchanger from ceramic. In this case, a wall of the ceramic heat exchanger represents electrically insulating layer 74. This wall prevents an additional heat transfer.

The illustration in FIG. 2 shows that the thermoelectric module according to the example construction according to the present invention includes a plurality of alternating p- and n-conductive legs 54, 56 which are positioned beside each other in series within block 58. Due to the alternating system of adjacently positioned p-n-doped legs 54, 56, which are preferably manufactured from a semiconductor material, it is ensured already during the manufacture of block 58 that, during operation of the thermoelectric module in the form of a block 58 proposed according to the present invention, a meandering or looping current flow I (see reference numeral 52 in FIG. 2) is obtained. Due to the presence of gaps 66, which extend over a gap length 68, and due to the remaining bridges 70, a looping or meandering current flow I is obtained (see position 52 in FIG. 2). On the one hand, the alternately positioned formation of gaps 66 achieved with the aid of sawing or cutting, or another metal-cutting process and the correspondingly following presence of bridges 70, produce an alternating electrically conductive connection in such a way that meandering current flow I shown in FIG. 2 results through block 58 from p-n-couples 60 of p-n-legs 54, 56. Due to the alternating sequence of bridges 70 and gaps 66, which may be filled up with air or with an electrically insulating material, an electrically conductive connection results which is alternately implemented on the upper and lower sides of p-n thermocouples 60. This results during operation of the example thermoelectric module according to the present invention in stripe-like or meandering current flow I, which is marked by reference numeral 52 in FIG. 2.

The thermoelectric voltage is a function of the Seebeck coefficient of the p-n-legs 54, 56 materials and the efficiently usable temperature difference which prevails at the points of contact of p-n-legs 54, 56, i.e., in the area of bridges 70, which remain in the material and which form an electrically conductive connection between individual p-n-legs 54, 56. Since contact layers may be omitted in the example system according to the present invention, heat transfers which are associated with heat losses are dispensed with so that the efficiently usable temperature difference increases. The larger the efficiently usable temperature difference is, the larger is the thermoelectric voltage and the greater is the efficiency of the thermoelectric generator.

FIG. 3 shows a perspective view of a system of p- and n-legs 54, 56.

The construction of block 58 may take place in such a way that p-n-legs 54, 56 are implemented as extended, bar-shaped elements 100, whose length 102 of stripe-like p-n-legs 54, 56 is greater than their width.

For this purpose, a plurality of stripe-like p-n-legs 54, 56, as shown in FIG. 2, are positioned in block 58. For the purpose of electric insulation, bar-shaped elements 100 are separated into sections 106 down to electrically insulating layer 74 along their length 102 with the aid of a metal-cutting tool. These sections 106 are thus electrically decoupled from the other sections 106 bordering along length 102. Here, too, the electric insulation may, for example, take place through air or doping using a non-conductive material, or electrically insulating gap 66 is filled up with an electrically insulating material.

The electrical contact between individual sections 106 is established with the aid of at least one current-conductive connection 108.

In order to manufacture the system of p- and n-legs 54, 56 of p-n-thermocouples 60 and for connecting them to a housing 72 of a heat exchanger, different techniques are possible. For example, electrically insulating layer 74, e.g., aluminum oxide, may be applied to block 58 with the aid of coating, e.g., printing, or a sintering process, preferably low-temperature sintering. This type of manufacture suggests itself in particular when insulating layer 74 is manufactured from ceramic materials.

It is also within the meaning of the approach proposed according to the present invention to join pre-manufactured blocks 58 and to separate them subsequently with the aid of metal-cutting manufacturing methods, e.g., sawing or slitting. Subsequently, the resulting intermediate spaces, i.e., gaps 66, are filled up with non-conductive materials, for example.

At the points of contact between the p- and n-conductive materials of p-n-legs 54, 56, a diffusion barrier may additionally be implemented in order to achieve an even better separation of the materials of the two adjacent p-n-legs 54, 56.

What is claimed is:

1. A thermoelectric module, comprising:
a plurality of p-n-couples, two adjacent p-n-legs forming one of the p-n-couples in each case, and being manufactured from conductive materials, wherein the p-n-legs are separated from each other in an alternating sequence by an electrically insulating gap which creates a meandering current flow.

2. The thermoelectric module as recited in claim 1, wherein bridges remain between the p-n-legs in an alternating sequence.

3. The thermoelectric module as recited in claim 1, wherein, for electric insulation, the gap is one of filled with air, filled with an electrically insulating material, or is doped with a non-conductive material.

4. The thermoelectric module as recited in claim 1, wherein each of the p-n-couples includes one p-doped semiconductor and one n-doped semiconductor.

5. The thermoelectric module as recited in claim 1, wherein, between an electrically insulating layer and a housing of a heat exchanger, a layer is provided which mechanically decouples a block of a plurality of p-n-legs from the housing of the heat exchanger.

6. The thermoelectric module as recited in claim 5, wherein the electrically insulating layer is a non-conductive adhesive and the electrically insulating layer simultaneously is the layer which mechanically decouples the block from housing of the heat exchanger.

7. The thermoelectric module as recited in claim 5, wherein the electrically insulating layer includes an electrically non-conductive material.

8. The thermoelectric module as recited in claim 7, wherein the material is a ceramic material.

9. The thermoelectric module as recited in claim 5, wherein the p-n-legs are bar-shaped elements.

10. The thermoelectric module as recited in claim 9, wherein the bar-shaped elements are separated into sections down to the electrically insulating layer with the aid of a metal-cutting tool, and the electrical contact between the individual sections takes place via at least one current-conductive connection.

11. The thermoelectric module as recited in claim 5, wherein the block is electrically insulated with respect to the housing of the heat exchanger via an aluminum oxide layer, the aluminum oxide layer being AL₂O₃.

12. The thermoelectric module as recited in claim 1, wherein the p-n-legs are connected to be electrically conductive alternately on an upper side and lower side for creating one of a looping or a meandering current flow.

13. A method for manufacturing a thermoelectric module, comprising:
providing a block formed from a plurality of p-n-couples, two adjacent p-n-legs forming one of the p-n-couples in each case, and being manufactured from conductive materials, wherein the p-n-legs are separated from each other in an alternating sequence by an electrically insulating gap which creates a meandering current flow; and
applying an electrically insulating layer to the block using one of a coating technique or a sintering process.

14. The method as recited in claim 13, wherein the gap is created using metal-cutting machining.
